(19) United States
(12) Patent Application Publication
(10) Pub. No.: US 2012/0156890 A1
(43) Pub. Date: Jun. 21, 2012

(54) IN-SITU LOW-K CAPPING TO IMPROVE INTEGRATION DAMAGE RESISTANCE

(75) Inventors: KANG SUB YIM, Palo Alto, CA (US); Jin XU, Fremont, CA (US); Sure NGO, Dublin, CA (US); Alexandros T. DEMOS, Fremont, CA (US)

(73) Assignee: APPLIED MATERIALS, INC., Santa Clara, CA (US)

(21) Appl. No.: 13/305,559

(22) Filed: Nov. 28, 2011

Related U.S. Application Data
(60) Provisional application No. 61/425,020, filed on Dec. 20, 2010.

(51) Int. Cl. H01L 21/3105

(52) U.S. Cl. 438/763; 257/E21.241

(57) ABSTRACT

A method and apparatus for forming low-k dielectric layers that include air gaps is provided. In one embodiment, a method of processing a substrate is provided. The method comprises disposing a substrate within a processing region, reacting an organosilicon compound, with an oxidizing gas, and a porogen providing precursor in the presence of a plasma to deposit a porogen containing low-k dielectric layer comprising silicon, oxygen, and carbon on the substrate, depositing a porous dielectric capping layer comprising silicon, oxygen and carbon on the porogen containing low-k dielectric layer, and ultraviolet (UV) curing the porogen containing low-k dielectric layer and the porous dielectric capping layer to remove at least a portion of the porogen from the porogen containing low-k dielectric layer through the porous dielectric capping layer to convert the porogen containing low-k dielectric layer to a porous low-k dielectric layer having air gaps.

### CROSS-REFERENCE TO RELATED APPLICATIONS

This application claims benefit of U.S. provisional patent application Ser. No. 61/425,020, filed Dec. 20, 2010, which is herein incorporated by reference.

### FIELD OF THE INVENTION

### BACKGROUND OF THE INVENTION

1. Field of the Invention

Embodiments of the present invention generally relate to the fabrication of integrated circuits. More particularly, embodiments of the present invention relate to methods for forming low-k dielectric layers that include air gaps.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 0.1 micron feature sizes, and tomorrow's facilities soon will be producing devices having even smaller feature sizes.

The continued reduction in device geometries has generated a demand for layers having lower dielectric constant (k) values because the capacitive coupling between adjacent metal lines must be reduced to further reduce the size of devices on integrated circuits. In particular, insulators having low dielectric constants, less than about 4.0, are desirable. Examples of insulators having low dielectric constants include spin-on glass, fluorine-doped silicon glass (FSG), carbon-doped oxide, and polytetrafluoroethylene (PTFE), which are all commercially available.

More recently, low dielectric constant organosilicon layers having k values less than about 3.5 have been developed. One method that has been used to develop low dielectric constant organosilicon layers has been to deposit the layers from a gas mixture comprising an organosilicon compound and a compound comprising thermally labile species or volatile groups and then post-treat the deposited layers to remove the thermally labile species or volatile groups, such as organic groups, from the deposited layers. The removal of the thermally labile species or volatile groups from the deposited layers creates nanometer-sized voids or “air-gaps” in the layers, which lowers the dielectric constant of the layers, e.g., to about 2.5, as air has a dielectric constant of approximately 1. However, the porous characteristics of such dielectric films lead to undesired damage after further integration steps (e.g. etching or chemical mechanical polishing (CMP)).

In view of the continuing decrease in integrated circuit feature sizes and increase in circuit density, there remains a need for a method of forming devices and films that have dielectric layers with even lower dielectric constants.

### SUMMARY OF THE INVENTION

Embodiments of the present invention generally relate to the fabrication of integrated circuits. More particularly, embodiments of the present invention relate to methods for forming low-k dielectric layers that include an air gap. In one embodiment, a method of processing a substrate is provided. The method comprises disposing a substrate within a processing region, reacting an organosilicon compound, with an oxidizing gas, and a porogen providing precursor in the presence of a plasma to deposit a porogen containing low-k dielectric layer comprising silicon, oxygen, and carbon on the substrate, depositing a porous dielectric capping layer comprising silicon, oxygen and carbon on the porogen containing low-k dielectric layer, and ultraviolet (UV) curing the porogen containing low-k dielectric layer and the porous dielectric capping layer to remove at least a portion of the porogen from the porogen containing low-k dielectric layer through the porous dielectric capping layer to convert the porogen containing low-k dielectric layer to a porous low-k dielectric layer having air gaps.

In another embodiment a method of processing a substrate is provided. The method comprises depositing a porogen containing low-k dielectric layer comprising silicon, oxygen, and carbon on a substrate positioned in a processing region of a processing chamber by a method comprising flowing an organosilicon compound into the processing region at a flow rate between 500 and 1,500 mgm, flowing a porogen providing precursor into the processing region at a flow rate between 1,000 and 2,000 mgm, flowing an oxidizing gas into the processing region at a flow rate between 100 and 500 sccm, and flowing a dilutant into the processing region at a flow rate between 1,500 and 2,200 sccm, wherein the organosilicon compound, the porogen providing precursor, the oxidizing gas, and the dilutant are reacted in the presence of a plasma, depositing a porous dielectric capping layer comprising silicon, oxygen and carbon on the porogen containing low-k dielectric layer by a porogen-free method comprising flowing the organosilicon compound at a flow rate between 500 and 1,500 mgm, flowing the oxidizing gas at a flow rate between 100 and 500 sccm, and flowing the dilutant at a flow rate between 2,400 and 3,400 sccm, wherein the organosilicon compound, the oxidizing gas, and the dilutant are reacted in the presence of a plasma, and ultraviolet (UV) curing the porogen containing low-k dielectric layer and the porous dielectric capping layer to remove at least a portion of the porogen from the porogen containing low-k dielectric layer through the porous dielectric capping layer to convert the porogen containing low-k dielectric layer to a porous low-k dielectric layer having air gaps.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional schematic diagram of an apparatus for depositing films according to embodiments described herein;

FIG. 2 is a flow chart illustrating a process for forming a porous low-k dielectric layer having air-gaps with a porous dielectric capping layer according to embodiments described herein;

FIGS. 3A-3E are schematic diagrams of the layers deposited on a substrate by the process of FIG. 2; and

FIG. 4 is a plot illustrating the percentage of carbon present in various low-k dielectric films deposited with and without a porous dielectric capping layer.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the present invention are described by reference to a method and apparatus for depositing a porous dielectric capping layer over a porogen containing low-k dielectric layer. The dielectric capping layer and the porogen containing low-k dielectric layer may then be exposed to a UV treatment process to liberate and outgas the porogen from the porogen containing low-k dielectric layer through the porous dielectric capping layer converting the porogen containing low-k dielectric layer to a low-k dielectric layer having air gaps.

Low-k dielectric materials based on SiCOH materials formed by methods of plasma-enhanced chemical vapor deposition (PECVD) have been developed. However, as previously discussed, as the size of the electronic devices is reduced, materials with a low dielectric constant (low-k) of less than 2.5 are required for micro-devices. One approach for ultra low-k materials is to fabricate hybrid organic-inorganic films using silicon precursors with organic functional groups chemically attached to silicon atoms. Thereafter, the films are annealed, resulting in the degradation of the weak organic molecules in the hybrid films. However, the porous characteristics of such low-k films (k<2.2) induce undesired damage after further integration steps. Embodiments described herein reduce such undesired damage using a new scheme for capping the porous low-k film. In certain embodiments described herein, a porous in-situ capping layer is deposited over a porogen containing low-k dielectric layer prior to air-gap formation. This porous dielectric capping layer may be a denser low-k film with lower porosity relative to the underlying low-k film resulting in better resistance against integration damage such as plasma treatment during barrier deposition and CMP processes while being permeable enough to allow the porogen to be outgassed to increase the porosity and lower the k value of the underlying dielectric film.

The term “organosilicon compound” as used herein is intended to refer to compounds containing carbon atoms in organic groups, and can be cyclic or linear. Organic groups may include alkyl, alkenyl, cyclohexenyl, and aryl groups in addition to functional derivatives thereof. Preferably, the organosilicon compounds include one or more carbon atoms attached to a silicon atom whereby the carbon atoms are not readily removed by oxidation at suitable processing conditions. The organosilicon compounds may also preferably include one or more oxygen atoms. In certain embodiments, a preferred organosilicon compound has an oxygen to silicon atom ratio of at least 1:1, and more preferably at least 2:1, such as about 4:1.

Suitable cyclic organosilicon compounds include a ring structure having three or more silicon atoms, and optionally one or more oxygen atoms. Commercially available cyclic organosilicon compounds include rings having alternating silicon and oxygen atoms with one or two alkyl groups bonded to the silicon atoms. Some exemplary cyclic organosilicon compounds include: 1,3,5-trisilano-2,4,6-trimethylene, (Si H₂CH₂—)₃-(cyclic); 1,3,5,7-tetramethylcyclotetrasiloxane (TMCTS) (SiHCH₃—O—)₄-(cyclic); octamethylcyclotetrasiloxane(OMCTS), (Si(CH₃)₂—O—)₄-(cyclic); 1,3,5,7,9-pentamethylcyclopentasiloxane, (SiHCH₃—O—)₅-(cyclic); 1,3,5,7-tetrasilano-2,6-dioxy-4,8-dimethylene, (SiH₂—CH₂—SiH₂—O—)₂-(cyclic); and hexamethylcyclotrisiloxane Si(CH₃)₂—O—)₃-(cyclic).

Suitable linear organosilicon compounds include organosilicon compounds having linear, branched structures, or cyclic side groups with one or more silicon atoms and one or more carbon atoms. The organosilicon compounds may further include one or more oxygen atoms. Some exemplary linear organosilicon compounds include: methylsilane, CH₃—SiH₃; dimethylsilane, (CH₃)₂—SiH₂; trimethylsilane, (CH₃)₃—SiH; ethylsilane, CH₃—CH₂—SiH₃; disilanomethane, SiH₃—CH₂—SiH₃; bis(methylsilano)methane, CH₃—SiH₂—CH₂—SiH₂—CH₃; 1,2-disilanoethane, SiH₃—CH₂—CH₂—SiH₃; 1,2-bis(methylsilano)ethane, CH₃—SiH₂—CH₂—CH₂—SiH₂—CH₃; 2,2-disilanopropane, SiH₃—C(CH₃)₂—SiH₃; diethoxymethylsilane (DEMS), CH₃—SiH—(O—CH₂—CH₃)₂; 1,3-dimethyldisiloxane, CH₃; 1,1,3,3-tetramethyldisiloxane, (CH₃)₂—SiH—O—SiH—(CH3)₂; hexamethyldisiloxane (HMDS), (CH₃)₃—Si—O—Si—(CH₃)₃; 1,3-bis(silanomethylene)disiloxane, (SiH₃—CH₂—SiH₂—)₂—O; bis(1-methyldisiloxanyl)methane, (CH₃—SiH₂—O—SiH₂—)₂—CH₂; 2,2-bis(1-methyldisiloxanyl)propane, (CH₃—SiH₂—O—SiH₂—)₂—C(CH₃)₂; hexamethoxydisiloxane (HMDOS), (CH₃O)₃—Si—O—Si—(OCH₃)₃; dimethyldimethoxysilane (DMDMOS), (CH₃O)₂—Si—(CH₃)₂; dimethoxymethylvinylsilane (DMMVS), (CH₃O)₂—Si—(CH₃)—CH₂—CH₃.

The porogen-providing precursor including one or more organic compounds having at least one cyclic group is referred to as a porogen or porogen material. The term “cyclic group” as used herein is intended to refer to a ring structure. The ring structure may contain as few as three atoms. The atoms may include carbon, silicon, nitrogen, oxygen, fluorine, and combinations thereof, for example. The cyclic group may include one or more single bonds, double bonds, triple bonds, and any combination thereof. For example, a cyclic group may include one or more aromatics, aryls, phenyls, cyclohexanes, cyclohexadienes, cycloheptadienes, and combinations thereof. The cyclic group may also be bi-cyclic or tri-cyclic. Further, the cyclic group is preferably bonded to a linear or branched functional group. The linear or branched functional group preferably contains an alkyl or vinyl alkyl group and has between one and twenty carbon atoms. The linear or branched functional group may also include oxygen atoms, such as a ketone, ether, and ester. Some exemplary compounds having at least one cyclic group include alpha-terpinene (ATP), vinylcyclohexane (VCH), and phenylacetate, just to name a few.

Suitable oxidizing gases include oxygen (O₂), ozone (O₃), carbon monoxide (CO), carbon dioxide (CO₂), water (H₂O), 2,3-butane dione or combinations thereof. Disassociation of oxygen or the oxygen containing compounds may occur in a microwave chamber prior to entering the deposition chamber to reduce excessive dissociation of the silicon containing compounds. Preferably, radio frequency (RF) power is applied to the reaction zone to increase dissociation.

Suitable dilutants include non-reactive gases and/or inert gases, for example, helium or argon.

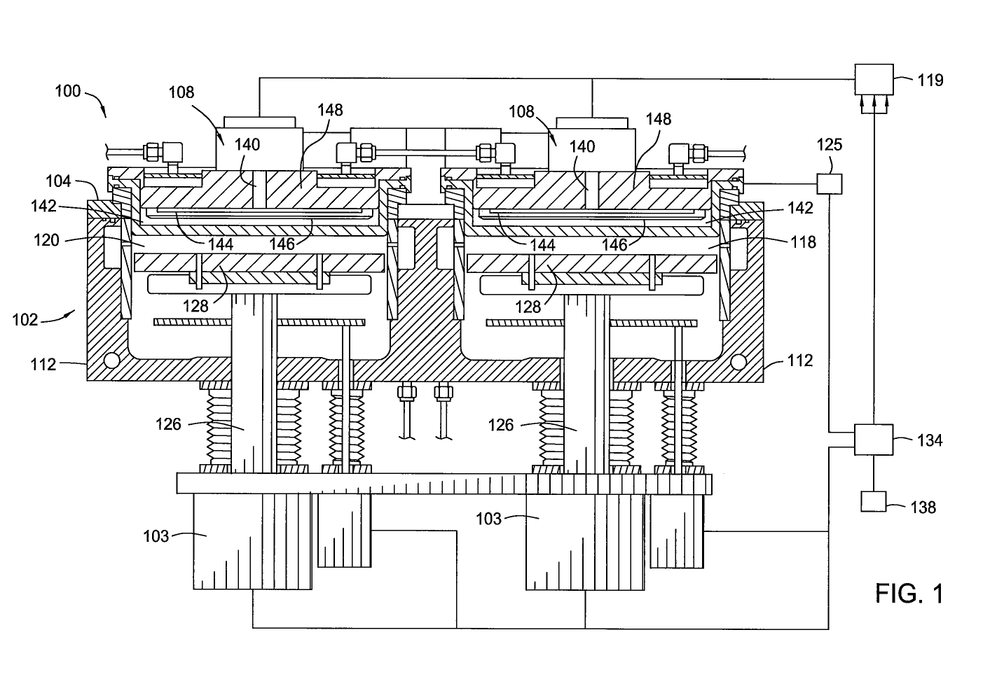

FIG. 1 is a cross-sectional, schematic diagram of a chemical vapor deposition (CVD) chamber 100 for depositing layers according to embodiments of the invention. An example of such a chamber is a dual or twin chamber on a PRODUCER® system, available from Applied Materials, Inc. of Santa Clara, Calif. The twin chamber has two isolated processing regions (for processing two substrates, one substrate per processing region) such that the flow rates experienced in each region are approximately one half of the flow rates into the whole chamber. The flow rates described in the examples below and throughout the specification are the flow rates per 300 mm substrate. A chamber having two isolated processing regions is further described in U.S. Pat. No. 5,855,681, which is incorporated by reference herein. Another example of a chamber that may be used is a DxZ® chamber on a CENTURA® system, both of which are available from Applied Materials, Inc.

The CVD chamber 100 has a chamber body 102 that defines separate processing regions 118, 120. Each processing region 118, 120 has a pedestal 128 for supporting a substrate (not shown) within the CVD chamber 100. Each pedestal 128 typically includes a heating element (not shown). Preferably, each pedestal 128 is movably disposed in one of the processing regions 118, 120 by a stem 126 which extends through the bottom of the chamber body 102 where it is connected to a drive system 103.

Each of the processing regions 118, 120 also preferably includes a gas distribution assembly 108 disposed through a chamber lid 104 to deliver gases into the processing regions 118, 120. The gas distribution assembly 108 of each processing region normally includes a gas inlet passage 140 which delivers gas from a gas flow controller 119 into a gas distribution manifold 142, which is also known as a showerhead assembly. Gas flow controller 119 is typically used to control and regulate the flow rates of different process gases into the chamber. Other flow control components may include a liquid flow injection valve and liquid flow controller (not shown) if liquid precursors are used. The gas distribution manifold 142 comprises an annular base plate 148, a face plate 146, and a blocker plate 144 between the base plate 148 and the face plate 146. The gas distribution manifold 142 includes a plurality of nozzles (not shown) through which gaseous mixtures are injected during processing. An RF (radio frequency) power supply 125 provides a bias potential to the gas distribution manifold 142 to facilitate generation of a plasma between the showerhead assembly and the pedestal 128. During a plasma-enhanced chemical vapor deposition process, the pedestal 128 may serve as a cathode for generating the RF bias within the chamber body 102. The cathode is electrically coupled to an electrode power supply to generate a capacitive electric field in the CVD chamber 100. Typically an RF voltage is applied to the cathode while the chamber body 102 is electrically grounded. Power applied to the pedestal 128 creates a substrate bias in the form of a negative voltage on the upper surface of the substrate. This negative voltage is used to attract ions from the plasma formed in the CVD chamber 100 to the upper surface of the substrate.

During processing, process gases are uniformly distributed radially across the substrate surface. The plasma is formed from one or more process gases or a gas mixture by applying RF energy from the RF power supply 125 to the gas distribution manifold 142, which acts as a powered electrode. Film deposition takes place when the substrate is exposed to the plasma and the reactive gases provided therein. The chamber walls 112 are typically grounded. The RF power supply 125 can supply either a single or mixed-frequency RF signal to the gas distribution manifold 142 to enhance the decomposition of any gases introduced into the processing regions 118, 120.

A system controller 134 controls the functions of various components such as the RF power supply 125, the drive system 103, the gas flow controller 119, and other associated chamber and/or processing functions. The system controller 134 executes system control software stored in a memory 138, which in the preferred embodiment is a hard disk drive, and can include analog and digital input/output boards, interface boards, and stepper motor controller boards. Optical and/or magnetic sensors are generally used to move and determine the position of movable mechanical assemblies.

The above CVD system description is mainly for illustrative purposes, and other plasma processing chambers may also be employed for practicing embodiments of the invention.

During deposition on a 300 mm substrate, a controlled plasma is typically formed in the chamber adjacent to the substrate by RF energy applied to the showerhead using the RF power supply 125 as depicted in FIG. 1. Alternatively, RF power can be provided to the substrate support. The plasma may be generated using high frequency RF (HFRF) power, as well as low frequency RF (LFRF) power (e.g., dual frequency RF), constant RF, pulsed RF, or any other known or yet to be discovered plasma generation technique. The RF power supply 125 can supply a single frequency RF between about 5 MHz and about 300 MHz. In addition, the RF power supply 125 may also supply a single frequency LFRF between about 300 Hz and about 1,000 kHz to supply a mixed frequency to enhance the decomposition of reactive species of the process gas introduced into the process chamber. The RF power may be cycled or pulsed to reduce heating of the substrate and promote greater porosity in the deposited film. Suitable RF power may be a power in a range between about 10 W and about 5,000 W, preferably in a range between about 200 W and about 1,000 W. Suitable LFRF power may be a power in a range between about 0 W and about 5,000 W, preferably in a range between about 0 W and about 200 W.

During deposition, the substrate may be maintained at a temperature between about −20° C. and about 500° C., preferably between about 100° C. and about 450° C. The spacing between the substrate and the manifold may be between about 200 mils and about 1,200 mils. The deposition pressure may be between about 1 Torr and about 20 Torr, preferably between about 4 Torr and about 10 Torr. The deposition rate may be between about 2,000 Å/min. and about 20,000 Å/min.

Deposition of a Porous Dielectric Capping Layer

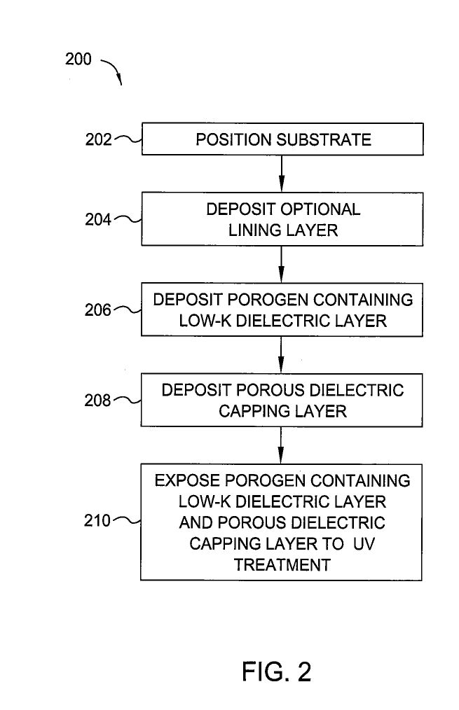

FIG. 2 is a flow chart illustrating a process 200 for forming a porous low-k dielectric layer having air-gaps with a porous dielectric capping layer according to embodiments described herein. At block 202, a substrate may be positioned into a processing region of a processing chamber. The processing chamber may be a PECVD chamber, such as the PECVD chamber depicted in FIG. 1. The processing region may be a processing region such as processing region 118 or 120 as depicted in FIG. 1.

At block 204, a lining layer may be deposited over the substrate. The lining layer may be a barrier layer deposited by a PECVD process from a plasma comprising a reactive silicon containing compound. The deposition process for the barrier layer can include a capacitively coupled plasma or both a capacitively coupled and inductively coupled plasma formed in the processing region according to embodiments described herein. An inert gas such as helium or argon may be used during plasma formation.

At block 206, a porogen containing low-k dielectric layer is deposited over the substrate. In embodiments where the lining layer is present, the porogen containing low-k dielectric layer may be deposited over the lining layer. The porogen containing low-k dielectric layer may be deposited by depositing a silicon/oxygen containing material that further contains thermally liable organic groups or porogens.

At block 208, a porous dielectric capping layer of the present invention may then be deposited over the porogen containing low-k dielectric layer. The porous dielectric capping layer may be deposited in the same processing region and/or processing chamber as the porogen containing low-k dielectric layer. The porous dielectric capping layer may be deposited using a back-to-back plasma process. The porous dielectric capping layer may be deposited using the same precursors as the porogen containing low-k dielectric layer deposited in block 206, except that the porous dielectric capping layer is generally porogen free. The porous dielectric capping layer may also be deposited using similar processing conditions to the processing conditions used for the porogen containing low-k dielectric layer. The substrate may be removed from the processing chamber and transferred to a UV treatment chamber. The porous dielectric capping layer may be a porous dielectric low-k capping layer. In certain embodiments, the porous dielectric capping layer is a porous oxide dielectric capping layer. One exemplary porous oxide dielectric capping layer is described in US 2003/0224591.

At block 210, the porogen containing low-k dielectric layer and porous dielectric capping layer are exposed to a UV treatment or “curing” process. Exposure of the porogen containing low-k dielectric layer and the porous dielectric capping layer to a UV curing process results in liberation of the porogen containing compound from the porogen containing low-k dielectric layer resulting in the formation of air pockets or “air gaps” within the dielectric layer. The porous dielectric capping layer generally has a lower porosity then the low-k dielectric layer having air-gaps. During the UV curing process, the gaseous porogen containing compound escapes through the porous dielectric capping layer. Therefore it is important that the porous dielectric capping layer be permeable enough to allow the gaseous porogen containing compound to escape while maintaining enough structural integrity to prevent the porous low-k dielectric layer from collapsing during subsequent integration steps.

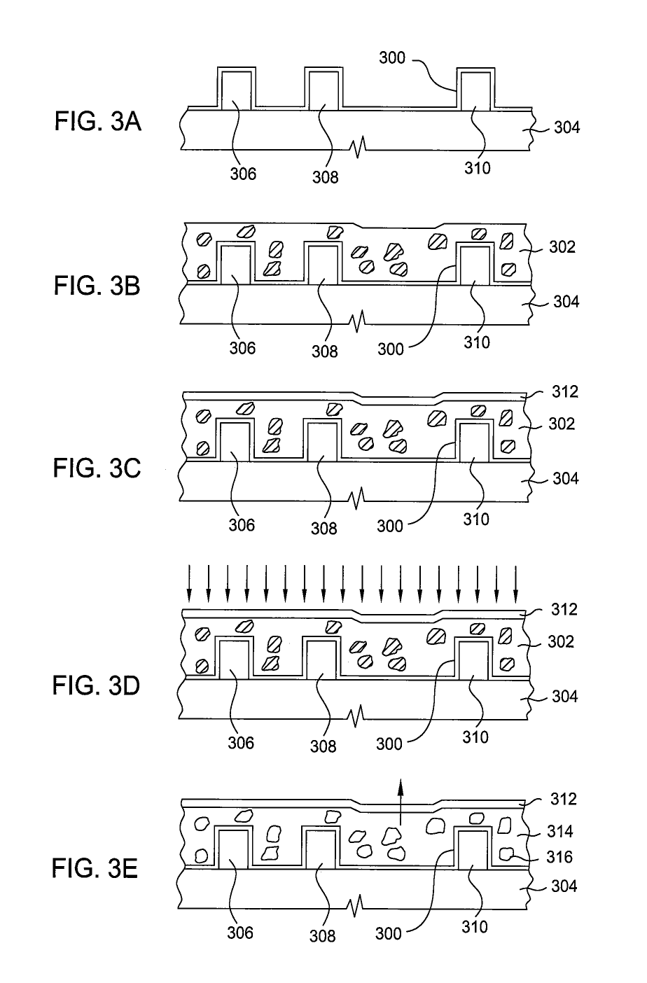

Referring to FIGS. 3A-3E, a lining layer 300 may be deposited on an underlying surface of a substrate 304. The lining layer 300 acts as an isolation layer between the subsequent porogen containing low-k dielectric layer 302 and the underlying surface of the substrate 304 and metal lines 306, 308, 310 formed on the surface of the substrate 304. The porogen containing low-k dielectric layer 302 is capped by a porous dielectric capping layer 312 as described herein.

Referring to FIG. 3A, the lining layer 300 may be deposited in the processing region 118, 120 by introducing a reactive silicon containing compound and an oxidizing gas. The process gases react in a plasma enhanced environment to form a conformal silicon oxide layer on the surface of the substrate 304 and metal lines 306, 308, 310.

Referring to FIG. 3B, the porogen containing low-k dielectric layer 302 is deposited from a processing gas consisting of a silicon containing precursor, for example, an organosilicon containing precursor, a porogen providing precursor, an optional oxidizing gas, and a dilutant. The porogen containing low-k dielectric layer 302 may be silicon oxycarbide layer. The silicon containing precursor gas may flow at a flow rate from about 100 to about 3,000 mgm. The porogen providing precursor gas may flow at a flow rate from about 100 to about 3,000 mgm. The optional oxidizing gas may flow at a flow rate from about 0 to about 5,000 sccm. The dilutant gas may flow at a flow rate from about 500 to about 5,000 sccm. The preferred gas flow rates range from about 200 to about 1,000 mgm for the silicon containing precursor, from about 200 to about 1,000 mgm for the porogen providing precursor, from about 100 to about 1,000 sccm for the oxidizing gas, and from about 1,500 sccm to about 2,200 sccm for the dilutant. Preferably, the processing region is maintained at a pressure from about 2 to about 15 Torr during deposition of the porogen containing low-k dielectric layer 302. More preferably, the processing region is maintained at a pressure from about 5 Torr to about 10 Torr. The substrate may be maintained at a temperature from about 0° C. to about 400° C. Preferably, the substrate may be maintained at a temperature from about 200° C. to about 350° C.

The porogen containing low-k dielectric layer 302 may have a thickness between about 10 Å and 20,000 Å. Preferably, the porogen containing low-k dielectric layer 302 may have a thickness between about 500 Å and 10,000 Å.

Referring to FIG. 3C, a porous dielectric capping layer 312 is deposited on the porogen containing low-k dielectric layer 302, preferably using similar materials and methods as used for the deposition of the porogen containing low-k dielectric layer 302. The porous dielectric capping layer 312 may be a silicon oxycarbide layer. The porosity of the porous dielectric capping layer 312 may be controlled by varying any of the aforementioned process conditions including the flow rates of the silicon containing precursor, the oxidizing gas, and/or the dilutant gas. The porous dielectric capping layer 312 may be deposited using the process conditions described in Table I.

TABLE I
Process Conditions for Capping Layer
Process Conditions For Capping Layer

| | | |
|---|---|---|
| Temperature (° C.) | 0° C.-400° C. | 200° C.-350° C. |
| Pressure (Torr) | 1 Torr-15 Torr | 5 Torr-10 Torr |
| Heater Spacing (mils) | 200 mils-1,200 mils | 200 mils-400 mils |
| Power (Watts) | 50 W-2,000 W | 200 W-500 W |
| Flow Rates | | |
| Silicon Precursor (mgm) | 100 mgm-3,000 mgm | 200 mgm-1,000 mgm |
| Oxidant (sccm) | 0-5,000 sccm | 100-1,000 sccm |
| Dilutant (sccm) | 500-5,000 sccm | 2,400-3,400 sccm |

The porous dielectric capping layer 312 may have a thickness between about 100 Å and 1,000 Å. Preferably, the porous dielectric capping layer 312 may have a thickness between about 200 Å and 600 Å.

As shown in FIGS. 3D and 3E, the porogen containing low-k dielectric layer 302 and the porous dielectric capping layer 312 are cured using a UV curing process. The UV curing process volatilizes the porogen containing compounds which outgas through the pores of the porous dielectric capping layer 312 to convert the porogen containing low-k dielectric layer 302 to a porous low-k dielectric layer 314 having air-gaps 316.

An example of an ultra-violet cure process comprises providing a chamber pressure between about 2 torr and about 12 torr, providing a chamber temperature between about 50° C. and about 600° C., a UV source wavelength between about 200 nm and about 300 nm, a helium gas flow rate between about 100 sccm and 20,000 sccm, and optionally, additional gases such as argon, nitrogen, and oxygen or any combination thereof may be provided for the UV process. The UV power may be between about 25% and about 100% and the processing time period may be between about 0 minutes and about 200 minutes. The process may be carried out using a UV system manufactured by Applied Materials, Inc. of Santa Clara, Calif., for example a NanoCure system. Other UV systems, such as the system described in U.S. patent application Ser. No. 11/124,908, filed on May 9, 2005, entitled TANDEM UV CHAMBER FOR CURING DIELECTRIC MATERIALS, published as U.S. 2006/0251827, which is herein incorporated by reference to the extent not inconsistent with the current specification, may also be used. This process may be carried out using a static or dual-sweeping source.

The porous dielectric capping layer may have a porosity from about 10% to about 20% relative to a solid film formed from the same material and the porous low-k dielectric layer having air gaps may have a porosity from about 25% to about 40% relative to a solid film formed from the same material.

### EXAMPLES

Objects and advantages of the embodiments described herein are further illustrated by the following examples. The particular materials and amounts thereof, as well as other conditions and details, recited in these examples should not be used to limit embodiments described herein. The following examples demonstrate deposition of a porous low-k dielectric layer having air-gaps with a porous dielectric capping layer deposited thereon. This example is undertaken using a PRODUCER° system, available from Applied Materials, Inc. of Santa Clara, Calif.

The porous low-k dielectric layer having air gaps and the porous dielectric capping layer were deposited in a back-to-back process using the process conditions depicted in Table II. As shown in Table II, the porous dielectric capping layer was deposited using a porogen free deposition process.

TABLE II
Process conditions for Example I
Process Conditions for Example 1

| | Low-k Dielectric | |
|---|---|---|
| | Deposition | Capping Layer |
| Temperature (° C.) | 260 | 260 |
| Pressure (Torr) | 7.5 | 7.5 |
| Heater Spacing (mils) | 300 | 300 |
| Power (Watts) | 500 | 250 |
| Flow Rates: | | |
| Silicon Precursor (mgm) | 1,000 | 1,000 |
| Porogen (mgm) | 1,500 | 0 |
| Oxidant (sccm) | 200 | 200 |
| Dilutant (sccm) | 2,000 | 3,000 |

The porogen containing low-k dielectric layer was deposited to a thickness of about 5,000 Å and the porous dielectric capping layer was deposited to a thickness of about 400 Å. Identical silicon containing precursors were used for deposition of the porogen containing low-k dielectric layer and the porous dielectric capping layer.

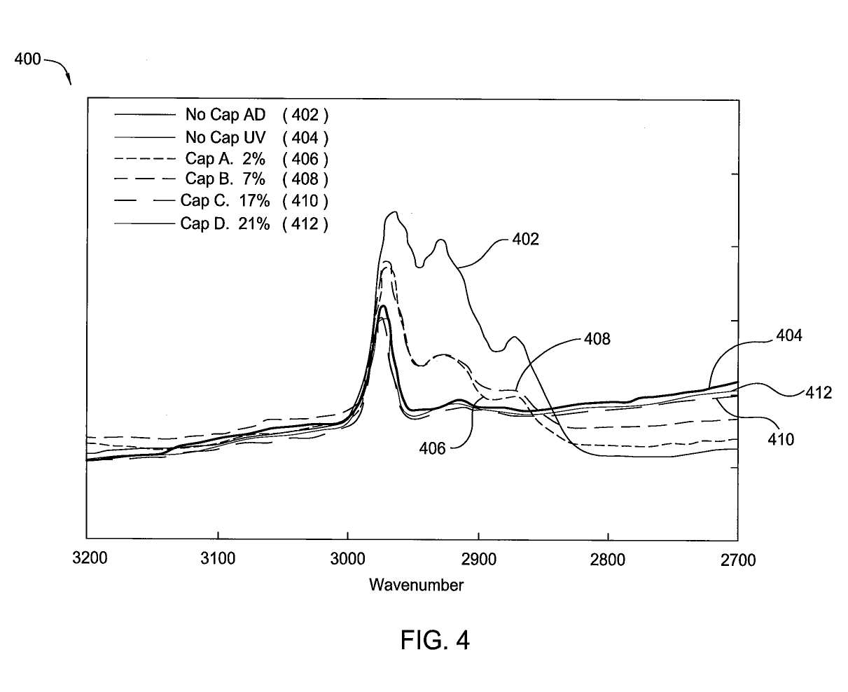

FIG. 4 is a plot 400 illustrating the percentage of carbon present in various low-k dielectric films deposited with and without a porous dielectric capping layer. The data depicted in FIG. 4 was obtained using Fourier transform-infrared (FT_IR) spectroscopy techniques. Line 402 represents the control prior to UV treatment in which no porous dielectric capping layer was used. Line 404 represents the control after UV treatment in which no capping layer was used. Line 406 represents a porous dielectric capping layer A having a porosity of about 2%. Line 408 represents a porous dielectric capping layer B having a porosity of about 7%. Line 410 represents a porous dielectric capping layer C having a porosity of about 17%. Line 412 represents a porous dielectric capping layer D having a porosity of about 21%. As demonstrated in plot 400, after curing, the porogen was completely removed from the porogen containing low-k dielectric layer with Cap C and Cap D, however, Cap A and Cap B blocked the porogen removal resulting in a high residue of C—H peaks near 2900 cm⁻¹. From the results depicted in plot 400, it is believed that a porous dielectric capping layer having a porosity of about 15% or greater is permeable enough for porogen outgassing.

Certain embodiments described herein provide a new process of in-situ capping for porous low-k dielectric films. The capping layer comprises denser SiCOH materials with low porosity, resulting in improved damage resistance against subsequent integration steps, while it is permeable enough to allow porogen to be outgassed to make low-k films underneath.

While the foregoing is directed to embodiments of the present invention, other and further embodiments of the invention may be devised without departing from the basic scope thereof, and the scope thereof is determined by the claims that follow.

1. A method of processing a substrate, comprising:
disposing a substrate within a processing region;
reacting an organosilicon compound, with an oxidizing gas, and a porogen providing precursor in the presence of a plasma to deposit a porogen containing low-k dielectric layer comprising silicon, oxygen, and carbon on the substrate;
depositing a porous dielectric capping layer comprising silicon, oxygen and carbon on the porogen containing low-k dielectric layer; and
ultraviolet (UV) curing the porogen containing low-k dielectric layer and the porous dielectric capping layer to remove at least a portion of the porogen from the porogen containing low-k dielectric layer through the porous dielectric capping layer to convert the porogen containing low-k dielectric layer to a porous low-k dielectric layer having air gaps.

2. The method of claim 1, wherein the porous dielectric capping layer has a porosity from about 10% to about 20% relative to a solid film formed from the same material and the porous low-k dielectric layer having air gaps has a porosity from about 25% to about 40% relative to a solid film formed from the same material.

3. The method of claim 1, wherein the reacting an organosilicon compound and the depositing a porous dielectric capping layer are performed back-to-back in the same processing chamber.

4. The method of claim 1, wherein the porous dielectric capping layer is a porogen-free dielectric capping layer.

5. The method of claim 1, wherein reacting an organosilicon compound with an oxidizing gas and a porogen to deposit a porogen containing low-k dielectric layer comprises:
flowing the organosilicon compound into the processing region at a flow rate between 500 and 1,500 mgm;
flowing the porogen providing precursor into the processing region at a flow rate between 1,000 and 2,000 mgm;
flowing an oxidizing gas into the processing region at a flow rate between 100 and 500 sccm; and
flowing a dilutant into the processing region at a flow rate between 1,500 and 2,200 sccm.

6. The method of claim 5, wherein depositing a porous dielectric capping layer comprising silicon, oxygen and carbon on the porogen containing low-k dielectric layer, comprises:
flowing the organosilicon compound into the processing region at a flow rate between 500 and 1,500 mgm;
flowing the oxidizing gas into the processing region at a flow rate between 100 and 500 sccm; and
flowing the dilutant into the processing region at a flow rate between 2,400 and 3,400 sccm.

7. The method of claim 6, wherein the porous dielectric capping layer is porogen-free.

8. The method of claim 1, wherein the porous low-k dielectric layer having air gaps has a dielectric constant of 2.2 or less following the UV cure step.

9. The method of claim 1, wherein the porous low-k dielectric layer having air gaps is a silicon oxycarbide layer.

10. The method of claim 9, wherein the porous dielectric capping layer is a silicon oxycarbide layer.

11. The method of claim 1, wherein the porous dielectric capping layer has a thickness between about 200 Å and about 600 Å.

12. The method of claim 6, wherein the porogen providing precursor is vinylcyclohexane, the oxidizer is oxygen, and the dilutant is helium.

13. The method of claim 12, wherein the organosilicon compound is selected from the group comprising: methylsilane CH₃—iH₃, dimethylsilane (CH₃)₂—SiH₂, trimethylsilane (CH₃)₃—SiH, ethylsilane CH₃—CH₂—SiH₃, disilanomethane SiH₃—CH₂—SiH₃, bis(methylsilano)methane CH₃—SiH₂—CH₂—SiH₂—CH₃, 1,2-disilanoethane SiH₃—CH₂—CH₂—SiH₃, 1,2-bis(methylsilano)ethane CH₃—SiH₂—CH₂—CH₂—SiH₂—CH₃, 2,2-disilanopropane SiH₃—C(CH₃)₂—SiH₃, diethoxymethylsilane (DEMS) CH₃—SiH—(O—CH₂—CH₃)₂, 1,3-dimethyldisiloxane CH₃—SiH₂—O—SiH₂—CH₃, 1,1,3,3-tetramethyldisiloxane (CH₃)₂—SiH—O—SiH—(CH3)₂, hexamethyldisiloxane (HMDS) (CH₃)₃—Si—O—Si—(CH₃)₃, 1,3-bis(silanomethylene)disiloxane (SiH₃—CH₂—SiH₂—)₂—O, bis(1-methyldisiloxanyl)methane (CH₃—SiH₂—O—SiH₂—)₂—CH₂, 2,2-bis(1-methyldisiloxanyl)propane (CH₃—SiH₂—O—SiH₂—)₂—C(CH₃)₂, hexamethoxydisiloxane (HMDOS) (CH₃O)₃—Si—O—Si—(OCH₃)₃, dimethyldimethoxysilane (DMDMOS) (CH₃O)₂—Si—(CH₃)₂, dimethoxymethylvinylsilane (DMMVS) (CH₃O)₂—Si—(CH₃)—CH₂—CH₃.

14. The method of claim 1, wherein the ultraviolet (UV) curing comprises:
providing a chamber pressure between about 2 torr and about 12 torr;
providing a chamber temperature between about 50° C. and about 600° C.;
providing a UV source wavelength between about 200 nm and about 300 nm; and
flowing helium gas at a flow rate between about 100 sccm and about 20,000 sccm.

15. A method of processing a substrate, comprising:
depositing a porogen containing low-k dielectric layer comprising silicon, oxygen, and carbon on a substrate positioned in a processing region of a processing chamber by a method comprising:
flowing an organosilicon compound into the processing region at a flow rate between 500 and 1,500 mgm;
flowing a porogen providing precursor into the processing region at a flow rate between 1,000 and 2,000 mgm;
flowing an oxidizing gas into the processing region at a flow rate between 100 and 500 sccm; and
flowing a dilutant into the processing region at a flow rate between 1,500 and 2,200 sccm, wherein the organosilicon compound, the porogen providing precursor, the oxidizing gas, and the dilutant are reacted in the presence of a plasma;
depositing a porous dielectric capping layer comprising silicon, oxygen and carbon on the porogen containing low-k dielectric layer by a porogen-free method comprising:
flowing the organosilicon compound at a flow rate between 500 and 1,500 mgm;
flowing the oxidizing gas at a flow rate between 100 and 500 sccm; and
flowing the dilutant at a flow rate between 2,400 and 3,400 sccm, wherein the organosilicon compound, the oxidizing gas, and the dilutant are reacted in the presence of a plasma; and
ultraviolet (UV) curing the porogen containing low-k dielectric layer and the porous dielectric capping layer to remove at least a portion of the porogen from the porogen containing low-k dielectric layer through the porous dielectric capping layer to convert the porogen containing low-k dielectric layer to a porous low-k dielectric layer having air gaps.

16. The method of claim 15, wherein the porous dielectric capping layer has a porosity from about 10% to about 20% relative to a solid film formed from the same material and the porous low-k dielectric layer having air gaps has a porosity from about 25% to about 40% relative to a solid film formed from the same material.

17. The method of claim 16, wherein the reacting an organosilicon compound and the depositing a porous dielectric capping layer are performed in-situ in the same processing chamber.

18. The method of claim 16, wherein the porogen providing precursor is vinylcyclohexane, the oxidizer is oxygen, and the dilutant is helium.

19. The method of claim 18, wherein the organosilicon compound is selected from the group comprising: methylsilane CH₃—SiH₃, dimethylsilane (CH₃)₂—SiH₂, trimethylsilane (CH₃)₃—SiH, ethylsilane CH₃—CH₂—SiH₃, disilanomethane SiH₃—CH₂—SiH₃, bis(methylsilano)methane CH₃—SiH₂—CH₂—SiH₂—CH₃, 1,2-disilanoethane SiH₃—CH₂—CH₂—SiH₃, 1,2-bis(methylsilano)ethane CH₃—SiH₂—CH₂—CH₂—SiH₂—CH₃, 2,2-disilanopropane SiH₃—C(CH₃)₂—SiH₃, diethoxymethylsilane (DEMS) CH₃—SiH—(O—CH₂—CH₃)₂, 1,3-dimethyldisiloxane CH₃—SiH₂—O—SiH₂—CH₃, 1,1,3,3-tetramethyldisiloxane (CH₃)₂—SiH—O—SiH—(CH3)₂, hexamethyldisiloxane (HMDS) (CH₃)₃—Si—O—Si—(CH₃)₃, 1,3-bis(silanomethylene)disiloxane bis(1-methyldisiloxanyl)methane (CH₃—SiH₂—O—SiH₂—)₂—CH₂, 2,2-bis(1-methyldisiloxanyl)propane (CH₃—SiH₂—O—SiH₂—)₂—C(CH₃)₂, hexamethoxydisiloxane (HMDOS) (CH₃O)₃—Si—O—Si—(OCH₃)₃, dimethyldimethoxysilane (DMDMOS) (CH₃O)₂—Si—(CH₃)₂, dimethoxymethylvinylsilane (DMMVS) (CH₃O)₂—Si—(CH₃)—CH₂—CH₃.

20. The method of claim 15, wherein the ultraviolet (UV) curing comprises:
providing a chamber pressure between about 2 torr and about 12 torr;
providing a chamber temperature between about 50° C. and about 600° C.;
providing a UV source wavelength between about 200 nm and about 300 nm; and
flowing helium gas at a flow rate between about 100 sccm and about 20,000 sccm.
